(19) United States
(12) Patent Application Publication
(10) Pub. No.: US 2014/0338744 A1
(43) Pub. Date: Nov. 20, 2014

(54) Process For Texturing The Surface Of A Silicon Substrate, Structured Substrate And Photovoltaic Device Comprising Such A Structured Substrate

(71) Applicants: TOTAL MARKETING SERVICES, Courbevoie (FR); CENTRE NATIONAL DE LA RECHERCHE SCIENTIFIQUE, Paris (FR); ECOLE POLYTECHNIQUE, Palaiseau (FR)

(72) Inventors: Nada Habka, Paris (FR); Pavel Bulkin, Villebon Sur Yvette (FR); Pere Roca i Cabarrocas, Villebon Sur Yvette (FR)

(21) Appl. No.: 14/367,607

(22) PCT Filed: Dec. 20, 2012
(86) PCT No.: PCT/EP2012/076338

§ 371 Date: Jun. 20, 2014

(30) Foreign Application Priority Data
Dec. 22, 2011 (FR) FR1104038

(51) Int. Cl. H01L 31/18; H01L 31/0236; H01L 31/028; H01L 21/3065; H01L 31/0352

(52) U.S. Cl. CPC H01L 31/1804; H01L 21/3065; H01L 31/035281; H01L 31/028; H01L 31/02363
USPC 136/256; 438/719; 257/618

(57) ABSTRACT

The invention relates to a process for texturing the surface of a silicon substrate, comprising a step of exposing said surface to an MDECR plasma generated, at least from argon, using between 1.5 W/cm² and 6.5 W/cm² of plasma power in a matrix distributed electron cyclotron resonance plasma source, the substrate bias being between 100 V and 300 V.

The present invention relates to a method for texturing the surface of a silicon substrate, a structured substrate and a photovoltaic device comprising such a textured substrate.

In the fabrication notably of photovoltaic cells, the texturing of substrates is widely used to reduce the light reflectivity on the surface of the cell and to improve the trapping of light in order to improve the efficiency of photovoltaic cells.

The texturing consists in forming by various methods structures at the nanometer and/or micrometer scale on the surface of the silicon.

The known structures formed are most often micrometer-scale pyramids or nanowires and nanocones.

Although these structures do indeed allow the surface reflectivity of the photovoltaic cells to be reduced, they also raise a certain number of problems when other layers of silicon are deposited on top.

Moreover, the methods currently known are quite costly and, notably for wet etching processes, raise environmental problems.

The document “Martin A Green, Jiannua Zhao, Aihua Wang and Stuart R Wenham, IEE Transactions on Electronic Devices, Vol. 46, No. 10, pp. 1940-1947 (1939)” describes for example a photolithographic and wet etching process allowing a silicon substrate c-Si (100) to be obtained with structures in the shape of inverted pyramids on its surface.

However, despite a significant reduction in the reflectivity, this process is long, costly, and polluting because it requires the use of large quantities of de-ionized water and of chemical solutions, such as solutions of KOH or NaOH, that need to be handled in an appropriate manner in order to comply with the environmental standards.

Another known method is for example presented in the document “J Yoo, Kyunghae Kim, M. Thamilselvan, N. Lakshminarayan, Young Kuk Kim, Jaehyeong Lee, Kwon Jong Yoo and Junsin Yi, Journal of Physics D: Applied Physics, Vol. 41, pp. 125205 (2008)” or in the French patent of the 24 Aug. 2009 deposition No 09 55767 PCT/FR201.0/051756 “Precédé de texturation de la surface d'un substrat de silicium et substrat de silicium texturé pour cellule solaire” [“Method of texturing the surface of a silicon substrate, and textured silicon substrate for a solar cell”]. The method here is based on a dry etching technique using a plasma of SF6/O2 in order to texture the surface of a crystalline silicon substrate c-Si (100).

Despite the fact that a texturing with a multitude of structures in the shape of needles or of pyramids on the surface of the silicon substrate and a reduction in reflectivity are obtained, the surface is such that a confcrmal deposition with a good passivation of another layer of silicon becomes difficult, or even impossible.

Moreover, the SF₆ also has a significant environmental impact, notably as regards greenhouse gases.

Thus, the invention aims to overcome, at least partially, the various drawbacks mentioned hereinabove.

For this purpose, one subject of the invention is a texturing method allowing a silicon substrate to be obtained having a low reflectivity, with a textured surface which may be used for the fabrication, of solar cells.

Thus, the invention relates to a method for texturing the surface of a silicon substrate, characterized in that it comprises a phase for exposure of said surface to a high-density plasma of Ar or of a mixture of Ar and H₂ with a power in the range between 1.5 W/cm² and 6.5 W/cm² and with a polarization of the substrate in the range between 100V and 300V.

According to other features, taken alone or in combination:

According to a first variant, the plasma is a high-density plasma of the matrix-distributed electron cyclotron resonance (MDECR) type.

According to a second variant, the plasma is a high-density plasma generated by inductive coupling (ICP).

According to a third variant, the high-density plasma is a plasma produced by resonant inductive coupling, also known as a Helicon plasma.

According to a fourth variant, the plasma is an expanding thermal plasma ETP.

According to a first aspect, for a plasma with a mixture of Ar and H₂, the flow of hydrogen is lower than the flow of argon.

More precisely, it is envisioned for the flow of argon to be three times higher than the flow of hydrogen.

According to a second aspect, the working pressure during the exposure phase is 0.7 pascal.

According to a third aspect, the exposure time of the surface to the high-density plasma of Ar or of a mixture of Ar and H₂ is longer than 1 minute, notably in the range between 1 and 30 minutes.

Furthermore, prior to said step for exposure to the high-density plasma of Ar or of a mixture of Ar and H₂, a texturing step is provided allowing micrometer-scale pyramids to be obtained.

According to another aspect, the silicon substrate is made of the crystalline silicon, notably oriented 100 or 111, in the polished, etched or rough-sawn state.

The invention also relates to a structured silicon substrate, characterized in that it comprises a textured surface comprising structures in the form of rolled-up planes.

According to a first variant, the rolled-up plane structures are structures in the form of unitary rolled-up planes.

According to a second variant, the textured surface comprises structures in the form of pyramids combined with the rolled-up planes.

The exposure to the high-density plasma is adjusted in such a manner that the rolled-up plane has a height of around 200 nm and a thickness of 20 nm.

According to another aspect, the mean external diameter of the unitary rolled-up structures is in the range between 150 nm and 250 nm.

According to yet another aspect, the mean external diameter and height of the binary structure is equivalent to those of the pyramids.

The base silicon substrate is for example crystalline silicon, notably oriented 100 or 111, in the polished, etched or rough-sawn state.

The structured silicon substrate such as defined hereinabove is notably obtained by the method such as defined hereinabove.

The invention also relates to a photovoltaic device, characterized in that it comprises a substrate structured with a textured surface such as defined hereinabove.

According to one embodiment, the photovoltaic device is composed of thin films.

According to another embodiment, the photovoltaic device is made of single-crystal silicon, notably a heterojunction photovoltaic device.

Other advantages and features of the invention will become apparent upon reading the description of the following figures, amongst which:

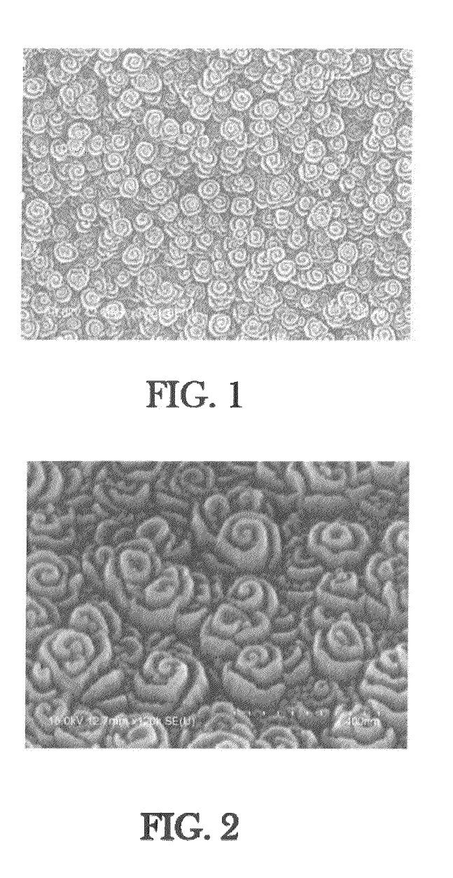

FIG. 1 shows an image obtained by a scanning electron microscope of the unitary structures obtained on a silicon substrate,

FIG. 2 shows an enlarged view of FIG. 1,

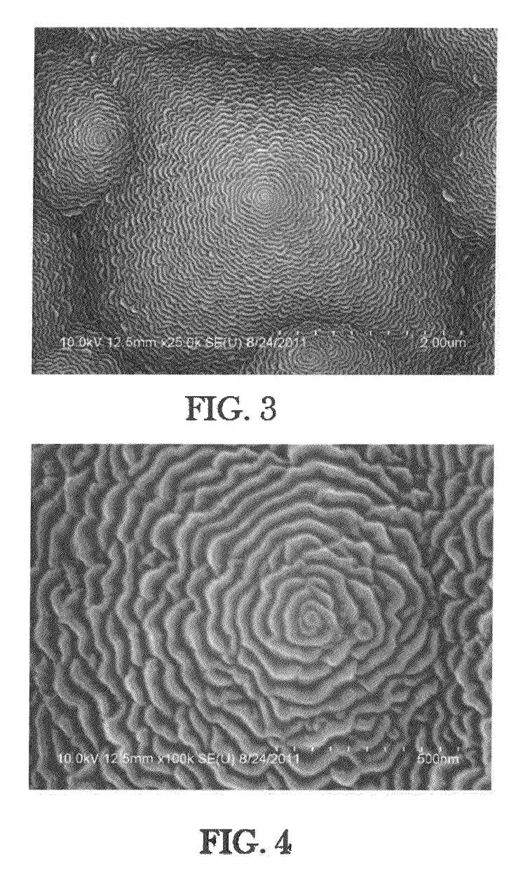

FIG. 3 shows an image obtained by a scanning electron microscope of the binary structures obtained on a silicon substrate already etched with micrometer-scale pyramids,

FIG. 4 shows an enlarged view of FIG. 3,

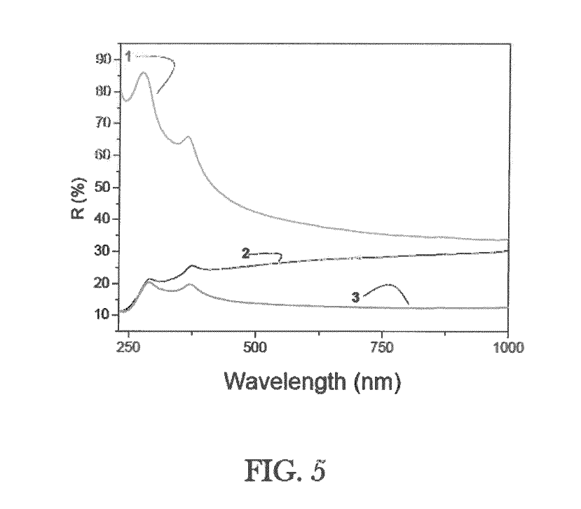

FIG. 5 shows a spectrum of the reflectivity as a function of the wavelength, on the one hand, of a polished silicon substrate surface without texturing and, on the other, of two unitary and binary textured substrates according to the invention.

The invention relates to a method for texturing the surface of a silicon substrate comprising a phase for exposure of said surface to a plasma of Ar (argon) or of a mixture of Ar and H₂, the plasma having a high density with a power in the range between 1.5 W/cm² and 6.5 W/cm², the bias voltage, obtained by applying an RF voltage to the substrate holder, is in the range between 100V and 300V.

Such a high-density plasma can be generated in various ways, for example by MDECR (for “Matrix Distributed Electron Cyclotron Resonance” or “Multi Dipolar Electron Cyclotron Resonance”), XCP (for “inductively coupled plasma”) or ETP (for “expanding thermal plasma”).

According to a first variant, the high-density plasma of Ar or of a mixture of Ar and H₂ may therefore be an MDECR plasma formed by an MDECR (for “Matrix Distributed Electron Cyclotron Resonance” or “Multi Dipolar Electron Cyclotron Resonance”) reactor which is well known per se in the field and will not be described in detail.

For one exemplary embodiment of an MDECR reactor, reference may in particular be made to the thesis by Laurent Kroely “Process and material challenges in high rate deposition of microcrystalline silicon thin films and solar cells by Matrix Distributed Electron Cyclotron Resonance Plasma”) submitted on 28 Sep. 2010 at the Ecole Polytechnique in France, in particular to the MDECR reactor of the ATOS type described starting from page 68 of this thesis and which was used for the implementation of the method and processing of the substrates according to the invention, or alternatively to the document FR 2 838 020 describing such a reactor.

In these reactors, a multipolar confinement of the electrons forming the plasma is implemented.

According to a second variant, the high-density plasma of Ar or of a mixture of Ar and H₂ may be an Inductively coupled plasma ICP or a plasma using resonant inductive coupling (Helicon plasma). An ICP plasma generator suitable for this purpose is for example described in the document US2010/0083902. In such a generator, the energy is supplied by electrical currents which are produced by magnetic induction, in other words magnetic fields varying over time.

According to a third variant, the high-density plasma of Ar or of a mixture of Ar and H₂ may be an ETP plasma. A generator for this purpose is for example described in the document EP 2 261 392. In an ETP plasma, a plasma is generated with a cascade arc source.

In the present case, the plasma is a high-density plasma of argon only, or is a mixture of hydrogen (H₂) and of argon (Ar). In this case, the flow of hydrogen is lower than the flow of argon, preferably with a ratio such that the flow of argon is three times higher than the flow of hydrogen.

It was concluded that it is the argon ions which are responsible for the observed texturing structures and that the hydrogen has the effect of providing uniformity over the whole of the textured surface.

For this plasma, the working pressure is of the order of 1.3 pascal (10 mtorr), and notably is 0.7 pascal (5 mtorr).

The exposure time to the aforementioned plasma is longer than 1 minute, notably in the range between 1 and 30 minutes. The higher the bias voltage, the higher the etch rate and the exposure time can be reduced.

Thus, with a bias voltage of 100V, an etch rate of 12 nm/min is obtained. In this case, an exposure time to the plasma of at least 30 minutes is recommended. Whereas, with a bias voltage of 200V, an etch rate of 200 nm/min may be reached with the pure Ar, allowing the exposure time to be reduced to a duration in the range between 1 and 20 min.

The silicon substrate to be textured can be crystalline silicon, notably oriented 100 or 111, for example in the polished, etched or rough-sawn state. In particular, it can be ultra-thin or ultra-thin films of silicon (rigid or flexible) with a thickness that can vary from 5 to 50 μm.

Depending on the initial configuration of the substrate, two different types of structures may be obtained referred to in the following as unitary structures and binary structures.

FIGS. 1 and 2 show images obtained by a scanning electron microscope of the texturing structures produced on the surface of a substrate of polished or rough-sawn Si.

A completely new texturing is obtained with structures in the form of rolled-up planes, notably a spiral or in the shape of a scroll. The term ‘rolled-up planes’ is understood to mean substantially vertical walls separated by furrows and running over the surface of the substrate in a curved fashion. It could even be said to take the form of a rose. This is the unitary structure, in other words all of the rolled-up planes around the same center.

The mean height of the unitary structures (for example a “rose”) is around 200 nm, and the mean external diameter of the unitary structures is in the range between 150 nm and 250 nm. The external diameter is understood to mean the diametric distance between the external surfaces of a unitary structure. The thickness of a rolled-up plane is around 20 nm.

FIGS. 3 and 4 show images obtained with a scanning electron microscope of the texturing structures produced on the previously etched surface of an Si substrate, for example in order to obtain micrometer-scale pyramids.

A completely new texturing is obtained with structures in the form of nanometer-scale rolled-up planes which are grafted onto the initial micrometer-scale etch pattern (pyramid); this is the binary or combined structure.

The dimensions of the combined structures are equivalent to those of the initial etch patterns.

FIG. 5 shows a first curve 1 showing the reflectivity as a function of wavelength of a polished silicon substrate Fz(100) prior to the exposure to an MDSCR plasma, and a second curve 2 showing the same sample after exposure to the plasma.

A significant reduction in the reflectivity is observed especially in the blue region (short wavelengths). With respect to a polished wafer, a decrease is observed in the reflectivity of 88.7% in the blue region, in other words for wavelengths shorter than 500 nm, and of 56% in the red region, in other words for wavelengths longer than 500 nm.

Thus, the absorption of light is enhanced, notably in the region of the higher energy radiation, in other words the blue region, and the conversion efficiency of the cell can be increased.

The method such as described hereinabove is very advantageous, since it allows a novel texturing to be obtained so as to form ‘black silicon’ under much more favorable environmental conditions.

Indeed, relative to SP₆, which is conventionally used for texturing and which has a global warming index of 22800 for the environment, the impact of hydrogen with an index of 0 and of argon with an index 5.8 is negligible.

Moreover, this method uses a “low temperature process”, typically lower than 200° C.

Furthermore, the method such as described hereinabove allows one chemical etch step to be eliminated and can be used in a continuous plasma process.

According to one variant, a combination of a texturing process, for example a wet chemical process, so as to obtain, micrometer-scale pyramids, with the process described hereinabove is also provided. A micrometer-scale chemical texturing combined with a nanometer-scale plasma texturing is thus produced, which is the multi-scale texturing allowing the binary or combined structures to be obtained.

For this purpose, prior to said step for exposure to the high-density plasma of Ar or of the mixture of Ar and H₂, a texturing step allowing these micrometer-scale pyramids to be formed is carried out.

A texturing step using a wet process, such as mentioned in the introduction, or that described in the document WO2011/023894, may for example be used.

The curve 3 shows the reflectivity spectra of the binary or combined structures. In this case, the decrease in reflectivity in the red region is in particular improved with respect to that of a texturing using a high-density plasma of Ar or of a mixture of Ar and H₂ alone.

With respect to a polished wafer, this combination of texturing steps allows a reduction in the reflectivity of 88.7% to be obtained in the blue region (effect of the plasma processing), in other words the wavelengths below 500 nm, and of 65% in the red region (effect of the chemical processing), in other words wavelengths above 500 nm.

Another subject of the invention is a photovoltaic device, comprising a structured substrate exhibiting a textured surface as described hereinabove, in other words with unitary or binary structures as described hereinabove having structures in the form of rolled-up planes.

The photovoltaic device can be a thin film device, or a photovoltaic device made of single-crystal silicon, notably a heterojunction device.

1. A method for texturing a surface of a silicon substrate, characterized in that it comprises a phase for exposure of said surface to a high-density plasma of Argon (Ar) or of a mixture of Ar and Hydrogen (H₂) with a power in a range between 1.5 Watts per centimeters squared (W/cm²) and 6.5 W/cm², together with a biasing of the substrate in a range between 100 vote (V) and 300V.

2. The texturing method as claimed in claim 1, characterized in that the plasma is a high-density plasma of a matrix-distributed electron cyclotron resonance (MDECR) type.

3. The texturing method as claimed in claim 1, characterized in that the plasma is a high-density plasma generated by inductive coupling (ICP).

4. The texturing method as claimed in claim 1, characterized in that the plasma is a plasma produced by resonant inductive coupling, also known as a Helicon plasma.

5. The texturing method as claimed in claim 1, characterized in that the plasma is an expanding thermal plasma (ETP).

6. The texturing method as claimed in claim 1 for a plasma of a mixture of Ar and H₂, characterized in that a flow of is lower than a flow of Ar.

7. The texturing method as claimed in claim 6, characterized in that the flow of Ar is three times higher than the flow of H₂.

8. The texturing method as claimed in claim 1, characterized in that a working pressure during the exposure phase is 0.7 pascal.

9. The texturing method as claimed in claim 1, characterized in that exposure time of the surface to the plasma of Ar or of a mixture of Ar and H₂ is longer than 1 minute, notably in a range between 1 and 30 minutes.

10. The texturing method as claimed in claim 1, characterized in that, prior to said phase for exposure to plasma of Ar or of a mixture of Ar and H₂, a texturing step is carried out that allows micrometer-scale pyramids to be obtained.

11. The texturing method as claimed in claim 1, characterized in that the silicon substrate is made of crystalline silicon, notably oriented on 100 or 111 faces, in a polished, etched or rough-sawn state.

12. A structured silicon substrate, characterized in that it comprises a textured surface comprising structures in a form of rolled-up planes.

13. The structured silicon substrate as claimed in claim 12, characterized in that the rolled-up plane structures are structures in a form of unitary rolled-up planes.

14. The structured silicon substrate as claimed in claim 12, characterized in that the textured surface comprises structures a form of pyramids combined with the rolled-up planes.

15. The structured silicon substrate as claimed in claim 12, characterized in that the rolled-up plane is around 200 nanometers (nm) height and 20 nm in thickness.

16. The structured silicon substrate as claimed in claim 15, characterized in that a mean external diameter of the rolled-up structures is in the range between 150 nanometers (nm) and 250 nm.

17. The structured silicon substrate as claimed in claim 14 characterized in that a mean external diameter and height of the rolled-up planes is equivalent to those of the pyramids.

18. The structured silicon substrate as claimed in claim 12, characterized in that the silicon substrate is made of crystalline silicon, notably oriented on 100 or 111 faces, in a polished, etched or rough-sawn state.

19. The structured silicon substrate as claimed in claim 12, characterized in that it is obtained by the method as claimed in claim 1.

20. A photovoltaic device, characterized in that it comprises a structured silicon substrate with a textured surface as claimed in claim 12.

21. The photovoltaic device as claimed in claim 20, characterized in that the photovoltaic device is a thin film device.

22. The photovoltaic device as claimed in claim 20, characterized in that the photovoltaic device is made of single-crystal silicon, notably a heterojunction photovoltaic device.
